(19) United States
(12) Patent Application Publication
(10) Pub. No.: US 2006/0003470 A1
(43) Pub. Date: Jan. 5, 2006

(54) Phase-change random access memory device and method for manufacturing the same

(76) Inventor: Heon Yong Chang, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 10/999,545

(22) Filed: Nov. 30, 2004

(30) Foreign Application Priority Data
Jun. 30, 2004 (KR) 2004-50127

(51) Int. Cl. H01L 21/00

(52) U.S. Cl. 438/3

(57) ABSTRACT

Disclosed are a phase-change random access memory device and a method for manufacturing the same, capable of improving a driving speed of the phase-change random access memory by reducing a contact surface between a bottom electrode and a phase-change layer. The phase-change random access memory device includes a first insulation layer formed on a semiconductor substrate and having a first contact hole for exposing a predetermined portion of the semiconductor substrate, a bottom electrode contact for filling the first contact hole, a first bottom electrode formed on the first insulation layer, a second bottom electrode spaced from the first bottom electrode by a predetermined distance, a second insulation layer formed on the first insulation layer, a phase-change layer pattern for filling the second contact hole, and a top electrode formed on the phase-change layer pattern.

### BACKGROUND OF THE INVENTION

1. Field of the Invention

The present invention relates to a semiconductor memory device, and more particularly to a phase-change random access memory device and a method for manufacturing the same, capable of improving a driving speed of the phase-change random access memory device by reducing a contact area between a bottom electrode and a phase-change layer in such a manner that an amount of current required for phase-changing the phase-change layer can be reduced.

2. Description of the Prior Art

Semiconductor devices are mainly classified into RAM (random access memory) devices, such as DRAM (dynamic random access memory) devices and SRAM (static random access memory) devices, and ROM (read only memory) devices. The RAM devices have volatile characteristics so that data stored therein are automatically erased as time goes by. In addition, the RAM devices may allow data to be inputted thereto or outputted therefrom at a high speed. The ROM (read only memory) devices can store data in permanent while allowing data to be inputted thereto or outputted therefrom at a low speed. Such memory devices may represent logic “0” or logic “1” depending on charges stored therein.

Herein, the DRAM device, which is a volatile memory device, is unable to retain data unless a refresh voltage is periodically applied thereto, so it requires higher charge storage capacity. For this reason, various attempts have been carried out in order to enlarge a surface area of a capacitor electrode. However, if the surface area of the capacitor electrode becomes enlarged, there is a difficulty to increase an integration degree of the DRAM device.

In the meantime, a non-volatile memory device -has a greater amount of charge storage capacity. Recently, demands for flash memory devices, such as EEPROM (electrically erasable and programmable ROM) devices, allowing data to be electrically inputted/outputted have been being increased.

Such a flash memory cell generally has a vertical-stack type gate structure including a floating gate formed on a silicon substrate. Typically, A multi gate structure includes at least one tunnel oxide layer or dielectric layer, and a control gate formed at an upper portion or a peripheral portion of the floating gate. Writing or erasing of data in the flash memory cell can be achieved by allowing charges to pass through the tunnel oxide layer. At this time, an operation voltage must be higher than a supply voltage. For this reason, the flash memory devices must be equipped with booster circuits so as to generate voltages required for writing or erasing the data.

Thus, there have been various attempts to develop new memory devices having non-volatile and random access characteristics and capable of increasing the integration degree thereof with a simple structure. One of such new memory devices is a phase-change random access memory (PRAM) device.

The phase-change random access memory device employs a chalcogenide layer as a phase-change layer. The chalcogenide layer is a compound layer including Ge, Sb and Te (hereinafter, referred to as a “GST layer”). The GST layer is electrically switched between an amorphous state and a crystalline state according to current, that is, Joule heat applied thereto.

FIG. 1 is a graph for explaining a method of programming or erasing data in a phase-change random access memory device, in which a transverse axis represents a time and a longitudinal axis represents a temperature applied to a phase-change layer.

As shown in FIG. 1, if the phase-change layer is rapidly quenched after the phase-change layer has been heated at a first predetermined temperature higher than a melting temperature (Tm) for a first period of time (t₁: first operation period), the phase-change layer is changed into an amorphous state (see, curve ‘A’). In contrast, if the phase-change layer is quenched after the phase-change layer has been heated at a second predetermined temperature lower than the melting temperature (Tm) and higher than a crystallization temperature (Tc) for a second predetermined period of time (t₂: second operation period) longer than the first operation period t₁, the phase-change layer is changed into a crystalline state (see, curve ‘B’).

Herein, resistivity of the phase-change layer having the amorphous state is higher than that of the phase-change layer having the crystalline state. Therefore, it is possible to determine whether information stored in the phase-change random access memory cell is logic “1” or logic “0” by detecting current applied to the phase-change layer in a read mode.

As mentioned above, Joule heat is necessary in order to phase-change the phase-change layer. In a conventional phase-change random access memory device, if high density current is applied to a contact surface of the phase-change layer, the crystalline state of the contact surface of the phase-change layer may be changed. At this time, it is noted that current density required for phase-changing the phase-change layer becomes lowered as the contact surface of the phase-change layer becomes reduced.

FIG. 2 is a sectional view for explaining a conventional phase-change random access memory device.

As shown in FIG. 2, the conventional phase-change random access memory device includes a semiconductor substrate 10 formed with a bottom electrode 11, a first insulation layer 12 formed on the bottom electrode 11 and having a first contact hole 13 for exposing a predetermined portion of the bottom electrode 11, a bottom electrode contact 14 for filling the first contact hole 13, a second insulation layer 15 formed on the first insulation layer 12 including the bottom electrode contact 14 and having a second contact hole 16 for exposing the bottom electrode contact 14, a phase-change layer 17 for filling the second contact hole 16, and a top electrode 18 formed on the second insulation layer 15 including the phase-change layer 17.

In such a conventional phase-change random access memory device, if current is applied between the bottom electrode 11 and the top electrode 18, the crystalline state of the phase-change layer 17 is changed at a contact surface 19 according to current intensity (that is, heat) applied to the contact surface 19 formed between the bottom electrode contact 14 and the phase-change layer 17. At this time, heat required for phase-changing the phase-change layer 17 may directly relate to the contact surface 19 formed between the bottom electrode contact 14 and the phase-change layer 17. Accordingly, it is necessary to minimize the size of the contact surface 19, if possible.

However, in the above conventional phase-change random access memory device, the bottom electrode 11 is connected to the phase-change layer 17 through the bottom electrode contact 14. Accordingly, the size of the contact surface between the bottom electrode contact 14 and the phase-change layer 17 is directly subject to a limitation of a photo process for the contact hole, so there is a difficulty to reduce the size of the contact surface. For this reason, an amount of current required for phase-changing the phase-change layer may increase, lowering the driving speed of the phase-change random access memory device.

### SUMMARY OF THE INVENTION

Accordingly, the present invention has been made to solve the above-mentioned problems occurring in the prior art, and an object of the present invention is to provide a phase-change random access memory device and a method for manufacturing the same, capable of improving a driving speed of the phase-change random access memory device and reducing an amount of current required for phase-changing a phase-change layer by minimizing a contact area between a bottom electrode and the phase-change layer.

In order to accomplish the above object, according to one aspect of the present invention, there is provided a phase-change random access memory device comprising: a first insulation layer formed on a semiconductor substrate including a predetermined bottom structure, the first insulation layer having a first contact hole for exposing a predetermined portion of the semiconductor substrate; a bottom electrode contact for filling the first contact hole; a first bottom electrode formed on the first insulation layer including the bottom electrode contact and connected to the bottom electrode contact, and a second bottom electrode spaced from the first bottom electrode by a predetermined distance; a second insulation layer formed on the first insulation layer including the first and second bottom electrodes, the second insulation layer having a second contact hole for exposing a predetermined portion of the first insulation layer formed between the first and second bottom electrodes; a phase-change layer pattern for filling the second contact hole; and a top electrode formed on the phase-change layer pattern.

According to the preferred embodiment of the present invention, the phase-change random access memory device further comprises a third insulation layer formed on the second insulation layer including the top electrode and having a third contact hole for partially exposing the top electrode, a top electrode contact for filling the third contact hole, and a metal pattern connected to the top electrode contact.

Each of the first and second bottom electrodes includes a lower electrode conductive layer and a hard mask layer, which are sequentially stacked. In addition, the phase-change layer pattern includes a GeSb₂Te₄ layer or a Ge₂Sb₂Te₅ layer. At this time, the phase-change layer pattern has a “T” shape.

In order to accomplish the above object, according to another aspect of the present invention, there is provided a method for manufacturing a phase-change random access memory device, the method comprising the steps of: forming a first insulation layer on a semiconductor substrate including a predetermined bottom structure, the first insulation layer having a first contact hole for exposing a predetermined portion of the semiconductor substrate; filling the first contact hole with a conductive layer, thereby forming a bottom electrode contact; forming a bottom electrode pattern on the first insulation layer including the bottom electrode contact, the bottom electrode pattern being connected to the bottom electrode contact; forming a second insulation layer on an entire surface of a resultant structure; selectively etching the second insulation layer and the bottom electrode pattern such that the first insulation layer is partially exposed, thereby forming a first bottom electrode connected to the bottom electrode contact, a second bottom electrode, and a second control hole for separating the first bottom electrode from the second bottom electrode; sequentially forming a phase-change layer and a top electrode conductive layer on the second insulation layer; and patterning the upper electrode conductive layer and the phase-change layer, thereby forming a phase-change layer pattern and a top electrode, respectively.

According to the preferred embodiment of the present invention, the bottom electrode pattern is formed by sequentially stacking a bottom electrode conductive layer and a hard mask layer. In addition, the phase-change layer pattern is formed through patterning the phase-change layer in a “T” shape.

According to the preferred embodiment of the present invention, the method further comprises the steps of forming a third insulation layer on the second insulation layer including the top electrode, selectively etching the third insulation layer such that the top electrode is partially exposed, thereby forming a third contact hole, and forming a top electrode contact for filling the third contact hole and a metal patter connected to the top electrode contact. At this time, the step of forming the top electrode contact and the metal pattern includes the substeps of forming a metal layer on the third insulation layer including the third contact hole such that the third contact hole is filled with the metal layer, and patterning the metal layer.

### BRIEF DESCRIPTION OF THE DRAWINGS

The above and other objects, features and advantages of the present invention will be more apparent from the following detailed description taken in conjunction with the accompanying drawings, in which:

FIG. 1 is a graph for explaining a method of programming or erasing data in a phase-change random access memory device;

FIG. 2 is a sectional view for explaining a conventional phase-change random access memory device;

FIG. 3 is a sectional view for explaining a phase-change random access memory device according to one embodiment of the present invention; and

FIGS. 4a to 4f are sectional views for explaining a method for fabricating a phase-change random access memory device according to one embodiment of the present invention.

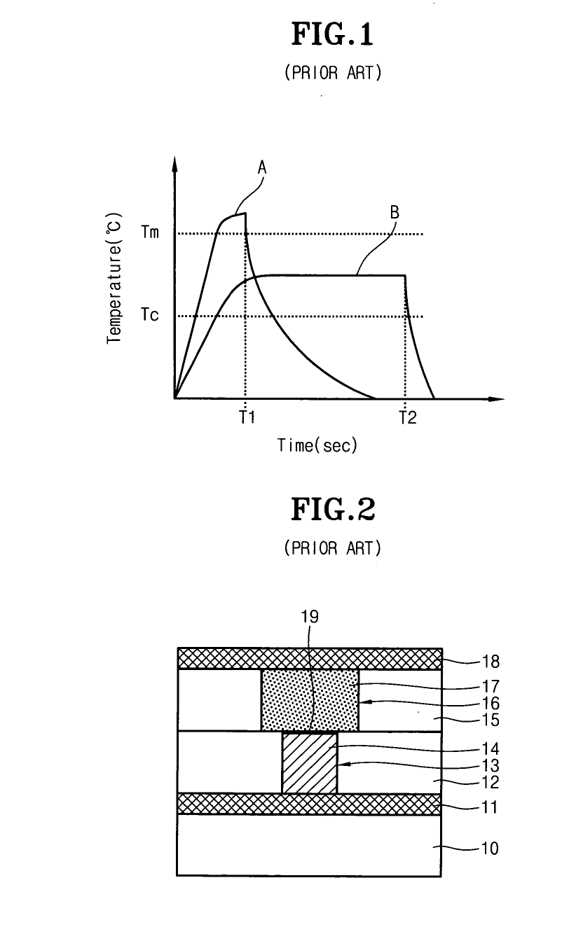

### DETAILED DESCRIPTION OF THE PREFERRED EMBODIMENTS

Hereinafter, the present invention will be described in detail with reference to accompanying drawings.

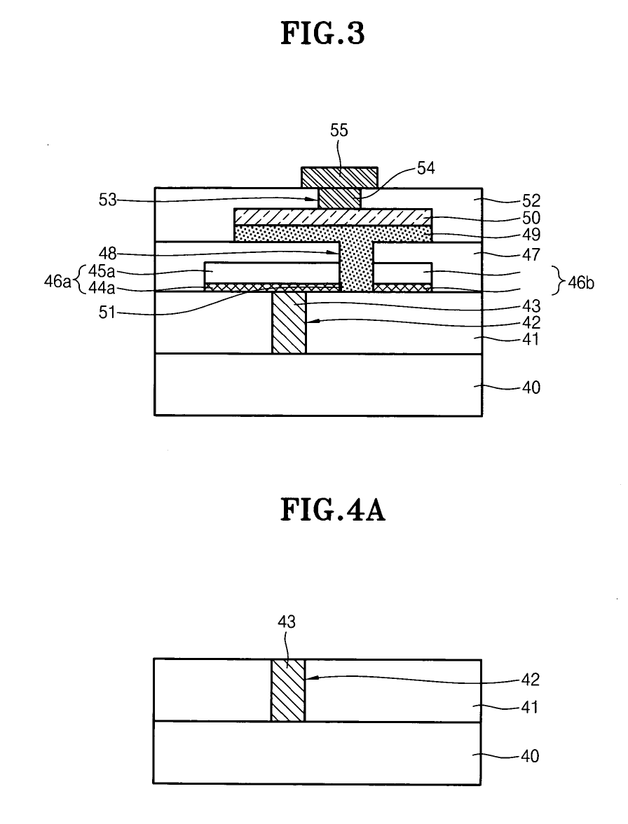

FIG. 3 is a sectional view for explaining a phase-change random access memory device according to one embodiment of the present invention.

As shown in FIG. 3, the phase-change random access memory device according to one embodiment of the present invention includes a semiconductor substrate 40 having a predetermined bottom structure (not shown), a first insulation layer 41 formed on the semiconductor substrate 40 and having a first contact hole 42 for exposing a predetermined portion of the semiconductor substrate 40, a bottom electrode contact 43 for filling the first contact hole 42, a first bottom electrode 46a formed on the first insulation layer 41 including the bottom electrode contact 43 and connected to the bottom electrode contact 43, a second bottom electrode 46b spaced from the first bottom electrode 46a by a predetermined distance, a second insulation layer 47 formed on the first insulation layer 41 including the first and second bottom electrodes 46a and 46b and having a second contact hole 48 for exposing a predetermined portion of the first insulation layer 41 formed between the first and second bottom electrodes 46a and 46b, a T-shape phase-change layer pattern 49 for filling the second contact hole 48, and a top electrode 50 formed on the T-shape phase-change layer pattern 49.

In addition, a third insulation layer 52 having a third contact hole 53 for partially exposing the top electrode 50 is formed on the second insulation layer 47 including the top electrode 50. A top electrode contact 54 is provided to fill the third contact hole 53 and a metal pattern 55 is formed on the third insulation layer 52 including the top electrode contact 54 and is connected to the top electrode contact 54.

The first bottom electrode 46a includes a first conductive layer 44a and a first hard mask layer 45a, which are sequentially stacked, and the second bottom electrode 46b includes a second conductive layer 44b and a second hard mask layer 45b, which are sequentially stacked. At this time, the first and second conductive layers 44a and 44b are made from polysilicon-based materials or metallic materials.

In addition, the second insulation layer 47 includes one selected from the group consisting of HDP, USG, SOG, PSG, BPSG, TEOS, and HLD oxide layers, and the top electrode 50 is made from polysilicon-based materials or metallic materials. The T-shape phase-change layer pattern 49 includes a GST layer. At this timed, a GeSb₂Te₄ layer or a Ge₂Sb₂Te₅ layer can be used as the GST layer.

A contact surface 51 is formed between the T-shape phase-change layer pattern 49 and the first conductive layer 44a forming the first bottom electrode 46a. If current is applied between the first bottom electrode 46a and the top electrode 50, the T-shape phase-change layer pattern 49 is phase-changed at an area of the contact surface 51. Since the size of the contact surface 51 depends on the thickness of the first conductive layer 44a forming the first bottom electrode 46a, it is necessary to minimize the thickness of the first conductive layer 44a in order to reduce the size of the contact surface 51.

The thickness of the first conductive layer 44a determining the size of the contact surface 51 is not influenced by a limitation of the photo process, so the thickness of the first conductive layer 44a can be formed with a desired size through a deposition process beyond the limitation of the photo process. Therefore, it is possible to reduce an amount of current required for phase-changing the T-shape phase-change layer pattern 49, thereby improving the driving speed of the phase-change random access memory device.

Meanwhile, since the second bottom electrode 46b is maintained in a floating state, the phase-change may not occur at a contact surface between the second conductive layer 44b forming the second bottom electrode 46b and the T-shape phase-change layer pattern 49.

Hereinafter, a method for fabricating the phase-change random access memory device shown in FIG. 3 will be described.

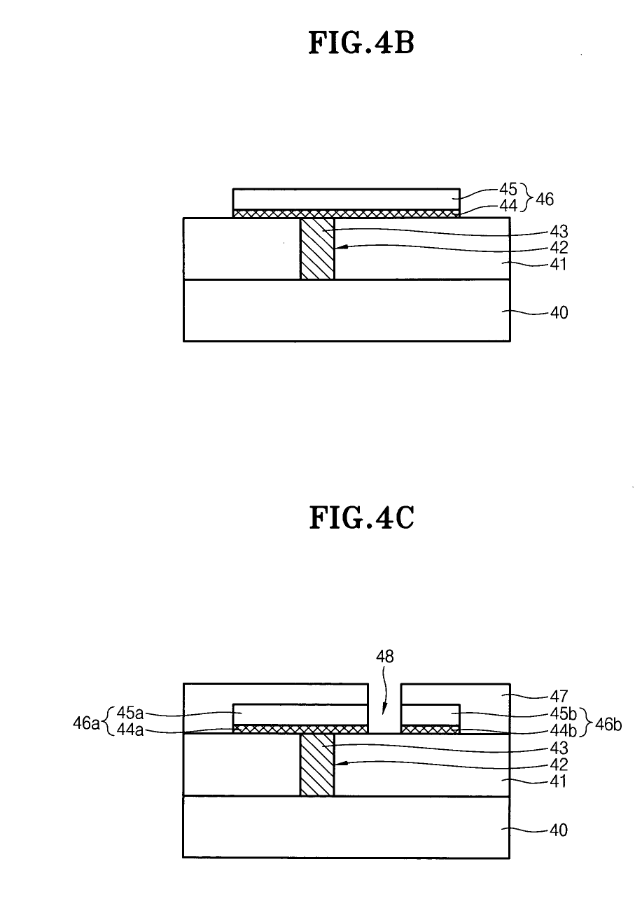

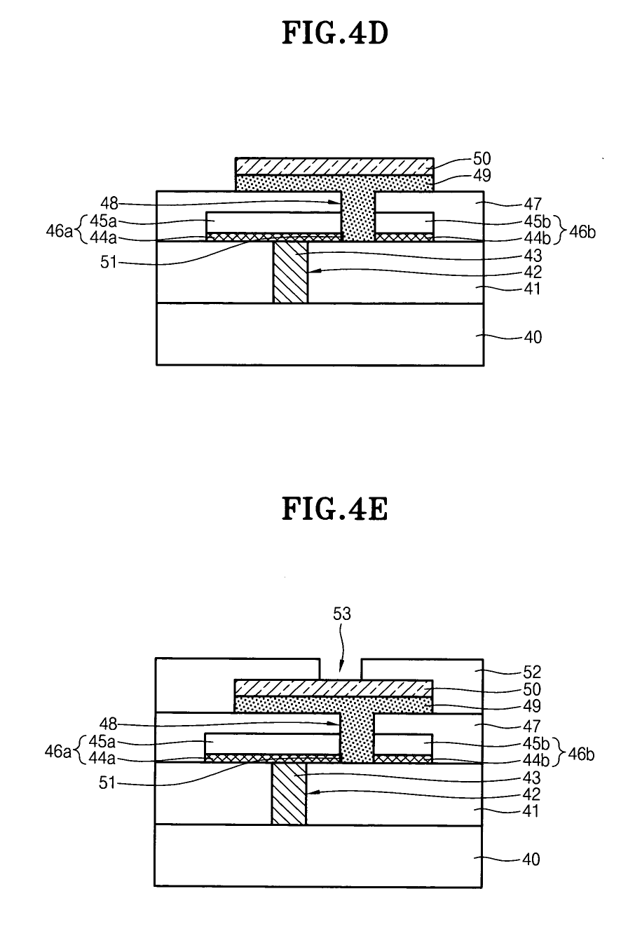

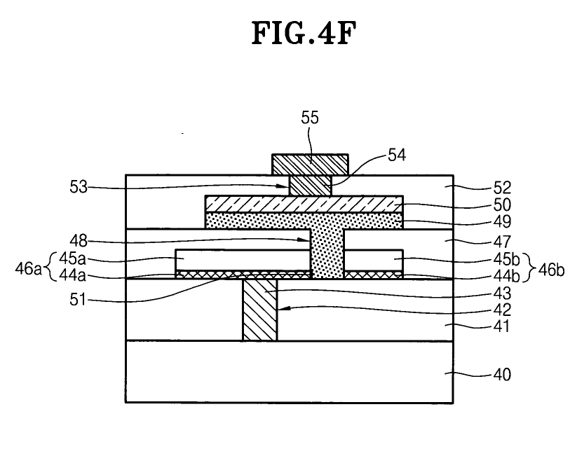

FIGS. 4a to 4f are sectional views for explaining the method for fabricating the phase-change random access memory device according to one embodiment of the present invention.

According to the method for fabricating the phase-change random access memory device of the present invention, as shown in FIG. 4a, the first insulation layer 41 having the first contact hole 42 exposing the predetermined portion of the semiconductor substrate 40 including the bottom structure (not shown) is formed on the semiconductor substrate 40. Then, the first contact hole 42 is filled with the conductive layer, thereby forming the bottom electrode contact 43.

After that, as shown in FIG. 4b, a bottom electrode pattern 46 connected to the bottom electrode contact 43 is formed on the first insulation layer 41 including the bottom electrode contact 43. Herein, the bottom electrode pattern 46 includes a bottom electrode conductive layer 44 and a hard mask layer 45 stacked on the bottom electrode conductive layer 44. In addition, the bottom electrode conductive layer 44 is made from polysilicon-based materials or metallic materials.

Then, as shown in FIG. 4c, the second insulation layer 47 is formed on an entire surface of the resultant structure such that the bottom electrode pattern is covered with the second insulation layer 47. As mentioned above, the second insulation layer 47 includes one selected from the group consisting of HDP, USG, SOG, PSG, BPSG, TEOS, and HLD oxide layers. After that, the second insulation layer 47 and the bottom electrode pattern are selectively etched such that the first insulation layer 41 is partially exposed, thereby forming the first bottom electrode connected to the bottom electrode contact 43, the second bottom electrode 46b, which is electrically floated, and the second control hole 48 for separating the first bottom electrode 46a from the second bottom electrode 46b.

The second contact hole 48 may be filled with the T-shape phase-change layer pattern in the next process. When the second contact hole 48 has been filled with the T-shape phase-change layer pattern, contact surfaces are formed at sidewalls of the first and second conductive layers 44a and 44b forming the first and second bottom electrodes 46a and 46b, respectively.

Since the first bottom electrode 46a is electrically connected to the bottom electrode contact 43 and the second bottom electrode 46b is electrically floated, the phase-change does not occur at the contact surface formed between the second conductive layer 44b forming the second bottom electrode 46b and the T-shape phase-change layer pattern, but may occur at the contact surface formed between the first conductive layer 44a forming the first bottom electrode 46a and the T-shape phase-change layer pattern.

Reference numerals 45a and 45b shown in FIG. 4c represent hard mask layers.

Then, as shown in FIG. 4d, a phase-change layer (not shown) is formed on the second insulation layer 47 in such a manner that the second contact hole 48 is filled with the phase-change layer and a top electrode conductive layer (not shown) is formed on the phase-change layer. Herein, the phase-change layer includes the GST layer. At this time, a GeSb₂Te₄ layer or a Ge₂Sb₂Te₅ layer can be used as the GST layer, and the top electrode conductive layer is made from polysilicon-based materials or metallic materials.

After that, the T-shape phase-change layer pattern 49 and the top electrode 50 are formed through patterning the top electrode conductive layer and the phase-change layer, respectively.

The contact surface 51 is formed between the T-shape phase-change layer pattern 49 and the first conductive layer 44a forming the first bottom electrode 46a. If current is applied between the first bottom electrode. 46a and the top electrode 50, the T-shape phase-change layer pattern 49 is phase-changed at an area of the contact surface 51. Since the size of the contact surface 51 depends on the thickness of the first conductive layer 44a forming the first bottom electrode 46a, it is possible to reduce the size of the contact surface 51 by minimizing the thickness of the first conductive layer 44a.

The thickness of the first conductive layer 44a determining the size of the contact surface 51 is not influenced by a limitation of the photo process, so the thickness of the first conductive layer 44a can be formed with a desired size through a deposition process beyond the limitation of the photo process. Therefore, it is possible to reduce an amount of current required for phase-changing the T-shape phase-change layer pattern 49, thereby improving the driving speed of the phase-change random access memory device.

Meanwhile, since the second bottom electrode 46b is maintained in a floating state, the phase-change may not occur at the contact surface between the second conductive layer 44b forming the second bottom electrode 46b and the T-shape phase-change layer pattern 49.

Then, as shown in FIG. 4e, the third insulation layer 52 is formed on the second insulation layer 47 including the top electrode 50. After that, the third insulation layer 52 is selectively etched such that the top electrode 50 is partially exposed, thereby forming the third contact hole 53.

In addition, as shown in FIG. 4f, a metal layer (not shown) is formed on the third insulation layer 52 including the third contact hole 53 in such a manner that the third contact hole 53 is filled with the metal layer. Then, the top electrode contact 54 for filling the third contact hole 53 and the metal pattern 55 connected to the top electrode contact 54 are formed by patterning the metal layer.

As described above, according to the present invention, the phase-change layer pattern is formed between the first bottom electrode connected to the bottom electrode contact and the second bottom electrode, which is floated while being spaced from the first bottom electrode by a predetermined distance, and the contact surface is defined between the first top electrode and the phase-change layer pattern according to the thickness of the first conductive layer forming the first bottom electrode.

As a result, the size of the contact surface formed between the first bottom electrode and the phase-change layer pattern, that is, the thickness of the conductive layer for the bottom electrode can be formed with a desired size through a deposition process beyond the limitation of the photo process. Accordingly, the present invention may reduce an amount of current required for phase-changing the phase-change layer pattern, thereby improving the driving speed of the phase-change random access memory device.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A phase-change random access memory device comprising:
a first insulation layer formed on a semiconductor substrate including a predetermined bottom structure, the first insulation layer having a first contact hole for exposing a predetermined portion of the semiconductor substrate;
a bottom electrode contact for filling the first contact hole;
a first bottom electrode formed on the first insulation layer including the bottom electrode contact and connected to the bottom electrode contact, and a second bottom electrode spaced from the first bottom electrode by a predetermined distance;
a second insulation layer formed on-the first insulation layer including the first and second bottom electrodes, the second insulation layer having a second contact hole for exposing a predetermined portion of the first insulation layer formed between the first and second bottom electrodes;
a phase-change layer pattern for filling the second contact hole; and
a top electrode formed on the phase-change layer pattern.

2. The phase-change random access memory device as claimed in claim 1, further comprising a third insulation layer formed on the second insulation layer including the top electrode and having a third contact hole for partially exposing the top electrode, a top electrode contact for filling the third contact hole, and a metal pattern connected to the top electrode contact.

3. The phase-change random access memory device as claimed in claim 1, wherein each of the first and second bottom electrodes includes a lower electrode conductive layer and a hard mask layer which are sequentially stacked.

4. The phase-change random access memory device as claimed in claim 1, wherein the phase-change layer pattern includes a GeSb₂Te₄ layer or a Ge₂Sb₂Te₅ layer.

5. The phase-change random access memory device as claimed in claim 1, wherein the phase-change layer pattern has a “T” shape.

6. A method for manufacturing a phase-change random access memory device, the method comprising the steps of:
i) forming a first insulation layer on a semiconductor substrate including a predetermined bottom structure, the first insulation layer having a first contact hole for exposing a predetermined portion of the semiconductor substrate;
ii) filling the first contact hole with a conductive layer, thereby forming a bottom electrode contact;
iii) forming a bottom electrode pattern on the first insulation layer including the bottom electrode contact, the bottom electrode pattern being connected to the bottom electrode contact;
iv) forming a second insulation layer on an entire surface of a resultant structure;
v) selectively etching the second insulation layer and the bottom electrode pattern such that the first insulation layer is partially exposed, thereby forming a first bottom electrode connected to the bottom electrode contact, a second bottom electrode, and a second control hole for separating the first bottom electrode from the second bottom electrode;
vi) sequentially forming a phase-change layer and a top electrode conductive layer on the second insulation layer; and
vii) patterning the upper electrode conductive layer and the phase-change layer, thereby forming a phase-change layer pattern and a top electrode, respectively.

7. The method as claimed in claim 6, wherein the bottom electrode pattern is formed by sequentially stacking a bottom electrode conductive layer and a hard mask layer.

8. The method as claimed in claim 6, wherein the phase-change layer pattern is formed through patterning the phase-change layer in a “T” shape.

9. The method as claimed in claim 6, further comprising the steps of:
forming a third insulation layer on the second insulation layer including the top electrode;
selectively etching the third insulation layer such that the top electrode is partially exposed, thereby forming a third contact hole; and
forming a top electrode contact for filling the third contact hole and a metal patter connected to the top electrode contact.

10. The method as claimed in claim 9, wherein the step of forming the top electrode contact and the metal pattern includes the substeps of forming a metal layer on the third insulation layer including the third contact hole such that the third contact hole is filled with the metal layer, and patterning the metal layer.

11. A phase-change random access memory device comprising:
a bottom electrode;
a phase-change layer pattern connected to one sidewall of the bottom electrode and having a “T” shape; and
a top electrode formed on the phase-change layer pattern.
